(19) United States
(12) Patent Application Publication
(10) Pub. No.: US 2023/0317572 A1
(43) Pub. Date: Oct. 5, 2023

(54) LEAD FRAME OF SEMICONDUCTOR DEVICE, INTEGRATED-TYPE LEAD FRAME OF SEMICONDUCTOR DEVICE, AND SEMICONDUCTOR DEVICE

(71) Applicant: Mitsubishi Electric Corporation, Tokyo (JP)

(72) Inventors: Kazufumi OKI, Tokyo (JP); Shogo SHIBATA, Tokyo (JP); Shuhei YOKOYAMA, Tokyo (JP)

(73) Assignee: Mitsubishi Electric Corporation, Tokyo (JP)

(21) Appl. No.: 18/069,699

(22) Filed: Dec. 21, 2022

(30) Foreign Application Priority Data
Mar. 29, 2022 (JP) 2022-053153

(51) Int. Cl. H01L 23/495; H01L 23/31; H01L 21/48; H01L 21/56

(52) U.S. Cl. CPC H01L 23/49555; H01L 23/3107; H01L 23/49503; H01L 21/4842; H01L 21/565

(57) ABSTRACT

Provided is a lead frame of a semiconductor device in which lead terminals with different terminal lengths can be formed without changing width of a frame portion. A lead frame includes: a first terminal portion in which a plurality of first terminals is arranged side by side; a second terminal portion in which a plurality of second terminals wider than the first terminals is arranged side by side; and a frame portion to which a tip end portion of each of the first terminals and the second terminals is connected, wherein first recess portions recessed along the first terminals are provided in the frame portion, and wherein the first terminal portion includes the first terminal the tip end portion of which is sandwiched between the adjacent first recess portions and the first terminal the tip end portion of which is not sandwiched between the adjacent first recess portions.

### BACKGROUND OF THE INVENTION

### Field of the Invention

The present disclosure relates to a lead frame of a semiconductor device, an integrated-type lead frame of a semiconductor device, and a semiconductor device.

### Description of the Background Art

There is a semiconductor device whose circuit is configured using a conductive lead frame. The lead frame is formed by applying press work or the like to a plate-form material of copper or the like. A region on which a semiconductor element for energization is mounted and lead terminals which enables energization between the semiconductor element and the outside are provided in the lead frame. Such a semiconductor device includes an insulating sealing resin covering the semiconductor element mounted on the lead frame. In such a semiconductor device, the conductive lead terminals electrically connected to the semiconductor element protrude from the side surface of the sealing resin, and the lead terminals are bent at right angles or obtuse angles. In such a semiconductor device, for the purpose of improving insulation property between the lead terminals, an arrangement of the terminals referred to as staggered arrangement may be adopted, in which lead terminals with long terminal length and lead terminals with short terminal length are arranged alternately in the direction perpendicular to the extending direction of the lead terminals.

Japanese Patent Application Laid-Open No. 2000-138343 discloses a lead frame in which the tip end portion of each of the lead terminals is connected to a frame portion being the outer frame of the lead frame at a time of forming the lead frame, and recesses are formed in the frame portion such that the tip end portion is sandwiched between the recesses. In this configuration, the frame portion is removed to separate each of the individual lead terminals after arranging a semiconductor element on the lead frame and sealing the semiconductor element by an insulating resin.

In Japanese Patent Application Laid-Open No. 2000-138343, a lead frame having lead terminals with different terminal lengths as in the case of the staggered arrangement is not described, recesses are provided adjacent to all terminals, and thus there is a problem that lead terminals with different terminal lengths cannot be formed without changing width of the frame portion.

### SUMMARY

Provided is a lead frame of a semiconductor device, an integrated-type lead frame of a semiconductor device, and a semiconductor device that have an effect of making it possible to form lead terminals with different terminal lengths without changing width of a frame portion.

A lead frame according to the present disclosure includes: a first terminal portion in which a plurality of first terminals is arranged side by side in a first direction being a width direction of the first terminals; a second terminal portion in which a plurality of second terminals wider in the first direction than the first terminals is arranged side by side in the first direction and which is arranged such that a die bond portion or a gap portion in which a semiconductor element is arranged is sandwiched between the first terminal portion and the second terminal portion; and a frame portion to which a tip end portion of each of the first terminals and the second terminals being an end portion that is farther from the die bond portion or the gap portion is connected. First recess portions recessed along the first terminals in a direction from the die bond portion or the gap portion to the tip end portions are provided in the frame portion. The first terminal portion includes the first terminal the tip end portion of which is sandwiched between the first recess portions adjacent in the first direction and the first terminal the tip end portion of which is not sandwiched between the first recess portions adjacent in the first direction.

An integrated-type lead frame according to the present disclosure is an integrated-type lead frame in which a plurality of the lead frames according to the present disclosure is arranged side by side at least in a second direction being an extending direction of the first terminals and the second terminals. The integrated-type lead frame includes a middle portion extending in the first direction of the lead frames between the lead frames adjacent in the second direction. The tip end portions of either of the first terminals and the second terminals are connected to each side of the frame portions extending in the first direction in the middle portion.

A semiconductor device according to the present disclosure includes: a lead frame having a plurality of first terminals arranged side by side in a first direction and a plurality of second terminals arranged side by side in the first direction; a die bond portion or a gap portion arranged to be sandwiched between the first terminals and the second terminals in a second direction being an extending direction of the first terminals and the second terminals; a semiconductor element arranged on the die bond portion or in the gap portion and electrically connected to the first terminals or the second terminals; and an insulating sealing resin sealing the die bond portion or the gap portion and the semiconductor element. At least either of the plurality of first terminals and the plurality of second terminals has two or more different terminal lengths from junction points with the sealing resin to tip ends.

With the above configurations, the lead terminals with different terminal lengths can be formed without changing width of the frame portion.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a lead frame of a first embodiment.

FIG. 2 is a plan view of a modification example of the lead frame of the first embodiment.

FIG. 3 is a plan view of a part of the lead frame of FIG. 1 on an enlarged scale.

FIG. 4 is a flowchart showing a method of manufacturing a semiconductor device using the lead frame of the first embodiment.

FIG. 5 is a plan view of the semiconductor device before a mounting and molding process using the lead frame of the first embodiment.

FIG. 6 is a plan view of the semiconductor device after the mounting and molding process using the lead frame of the first embodiment.

FIG. 7 is a side view of the semiconductor device of FIG. 6.

FIG. 8 is a plan view of the semiconductor device before a second forming process using the lead frame of the first embodiment.

FIG. 9 is a plan view of the semiconductor device after a second forming process using the lead frame of the first embodiment.

FIG. 10 is a side view of the semiconductor device of FIG. 9.

FIG. 11 is a plan view of the semiconductor device after a lead forming process using the lead frame of the first embodiment.

FIG. 12 is a side view of the semiconductor device of FIG. 11.

FIG. 13 is a plan view of a part of the semiconductor device before the lead forming process using the lead frame of the first embodiment on an enlarged scale.

FIG. 14 is a plan view of a modification example of the lead frame of the first embodiment.

FIG. 15 is a plan view of a part of the lead frame of FIG. 14 on an enlarged scale.

FIG. 16 is a plan view of a lead frame of a second embodiment.

FIG. 17 is a plan view of a lead frame of a third embodiment.

FIG. 18 is a plan view of an integrated-type lead frame of a fourth embodiment.

### DESCRIPTION OF THE PREFERRED EMBODIMENTS

### First Embodiment

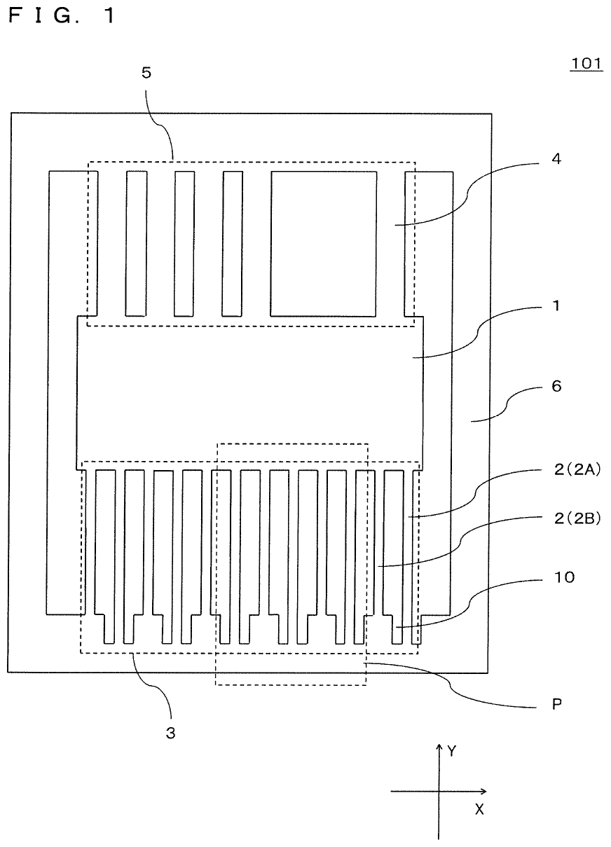

FIG. 1 is a plan view showing a lead frame 101 according to the first embodiment. This lead frame 101 composes lead terminals of a semiconductor device which includes the lead terminals arranged in a staggered way. Operations and effects of the lead frame 101 on the semiconductor device manufactured by using the lead frame 101 is described later. First, a configuration of the lead frame 101 is described. In the present disclosure, lead terminals may be simply referred to as terminals.

As shown in FIG. 1, the lead frame 101 includes: a die bond portion 1 on which a semiconductor element is arranged; a first terminal portion 3 in which a plurality of first terminals 2 being lead terminals is arranged side by side in a first direction (X direction) being the width direction of the first terminals 2; a second terminal portion 5 in which a plurality of second terminals 4 being lead terminals wider in the first direction than the first terminals 2 is arranged side by side in the first direction and which is arranged such that the die bond portion 1 is sandwiched between the first terminal portion 3 and the second terminal portion 5 in the second direction (Y direction) being the extending direction of the first terminals 2 and the second terminals 4; and a frame portion 6 to which the tip end portion of each of the first terminals and the second terminals being an end portion that is farther from the die bond portion 1 is connected and which annularly surround the die bond portion 1. The first direction (X direction) and the second direction (Y direction) are orthogonal to each other. Note that although an example in which the first direction (X direction) and the second direction (Y direction) are orthogonal to each other is presented in the present disclosure, the first direction and the second direction may not be orthogonal. For example, the angle between the first direction and the second direction can be appropriately adjusted in consideration of productivity of the lead frame.

The lead frame 101 is, for example, formed from a flat plate whose main material is aluminum, copper, or the like being conductive metals. The semiconductor element is arranged on the die bond portion 1. The first terminals 2 are, for example, control terminals for control signals. The second terminals 4, which is wider than the first terminals 2, are, for example, power terminals for main current. Note that the die bond portion 1 is not limited to rectangle as shown in FIG. 1. There may be several die bond regions that are electrically independent depending on wire connection form of the semiconductor device, and any electrical wiring pattern may be formed. Also, although a configuration in which all of the first terminals 2 and the second terminals 4 are integrally joined to the die bond portion 1 is shown in FIG. 1, actual configuration of the lead frame is not limited to the configuration shown in FIG. 1. FIG. 1 is a figure in which neighborhood of the die bond portion 1 is especially simplified for simplification of the description. In an actual lead frame, some of the terminals may not be integrally formed with the die bond portion and may be electrically connected to the die bond portion finally by wire bonding. Some of the terminals may not be electrically connected to the die bond portion and may be insulated from the die bond portion.

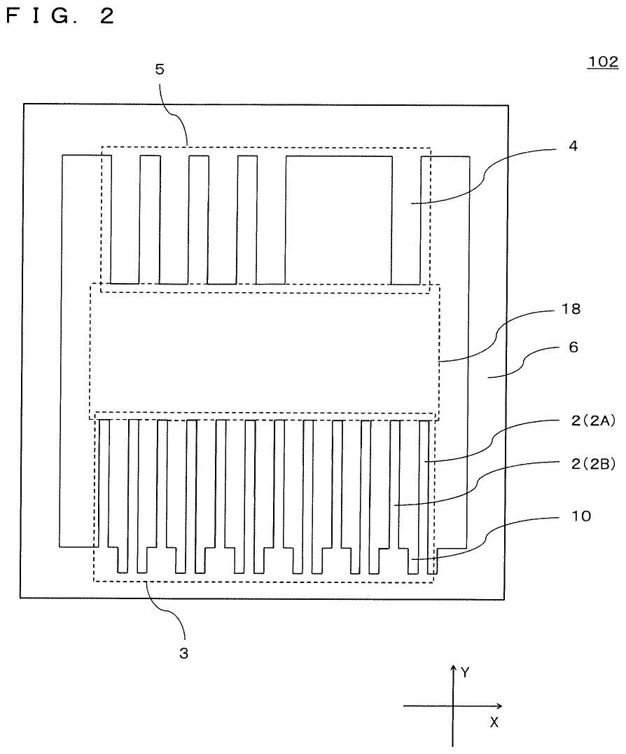

Furthermore, although a configuration in which the die bond portion 1 is integrally formed with the lead frame 101 is shown in FIG. 1, the die bond portion is not necessarily limited to this and may be configured by an insulating substrate or the like, for example. A lead frame 102 being a modification example of the lead frame 101 as described above is shown in FIG. 2. A part of the lead frame in the die bond region may be removed and replaced by a gap portion 18 in which an insulating substrate can be placed as shown in FIG. 2, for example.

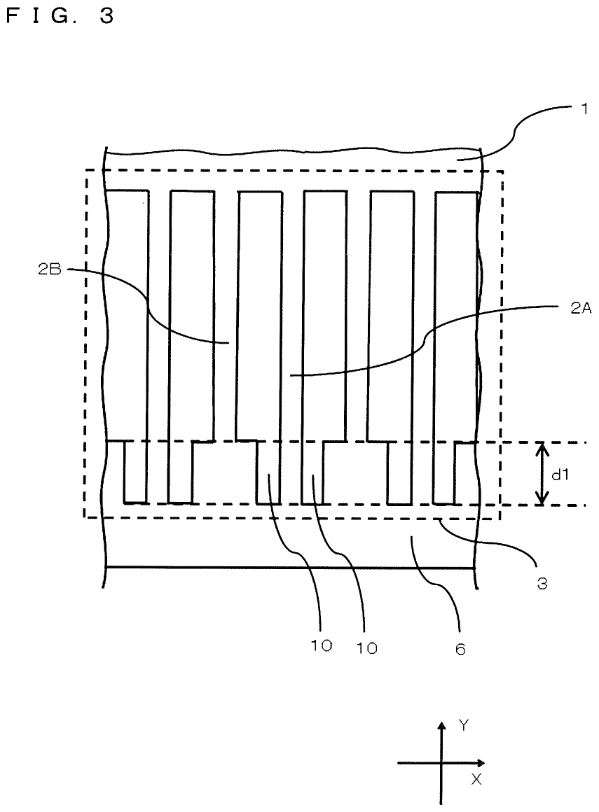

FIG. 3 is a plan view showing the part P of the lead frame 101 in FIG. 1 on an enlarged scale. A plurality of first recess portions 10 recessed along the first terminals 2 in the direction from the die bond portion 1 to the tip end portions of the first terminals 2 is provided in the frame portion 6. The tip end portions of the first terminals 2A are sandwiched between the first recess portions 10 adjacent in the first direction, and the first recess portions 10 have a linear shape to form the shape of the first terminals 2A in the side of the tip end portions of the first terminals 2A. Here, recess amount of the first recess portions 10 to the second direction is set to d1. In the first terminal portion 3, the first terminals 2A, the tip end portions of which are sandwiched between the first recess portions 10 adjacent in the first direction, and the first terminals 2B, the tip end portions of which are not sandwiched between the first recess portions 10 adjacent in the first direction, are arranged alternately.

Regarding the width in the first direction of the first recess portions 10, a space that allows usage of press dies or the like for cutting and separating of the first terminals 2A and the frame portion 6 is sufficient. The width in the first direction of the first recess portions 10 is desirably from 0.5 mm to 3 mm. If the width is less than 0.5 mm, it may be difficult to maintain strength of the press dies. Also, d1, which is the recess amount of the first recess portions 10 to the second direction, is desirably from 0.1 mm to 10 mm. If the recess amount is less than 0.1 mm, margin for adjustment of terminal length is small. If the recess amount exceeds 10 mm, width of the frame portion 6 needs to be large, ineffectual area of the lead frame 101, that is, an area of a part that is not finally used in the terminals or the like becomes large, and productivity deteriorates. More preferably, d1, which is the recess amount of the first recess portions 10 to the second direction, is more than or equal to 0.2 mm and less than or equal to 5 mm. With this configuration, margin for adjustment of terminal length and productivity are further maintained. Also, in the case where the width in the first direction of the first recess portions is from 0.5 mm to 1 mm, setting the recess amount d1 to the second direction to be up to twice the width in the first direction of the first recess portions make it easier to maintain strength of the press dies. Further, although the shape of the first recess portion 10 is rectangle, the shape of the recess portion is not limited to rectangle and may be deformed to triangle or the like as long as one side of the shape of the recess portion is parallel to and overlap the extended line of a side surface of the first terminal 2A.

The lead frame 101 is formed by, for example, blanking a metallic material being a flat plate by blanking press work using a die. This lead frame forming process is not different from the method to form a lead frame of prior art. In the forming of the lead frame 101 in the present disclosure, the lead frame 101 can be formed by setting the shape of the die such that the first recess portions 10 which sandwich the tip end portions of the first terminals 2A described above are formed in the frame portion 6.

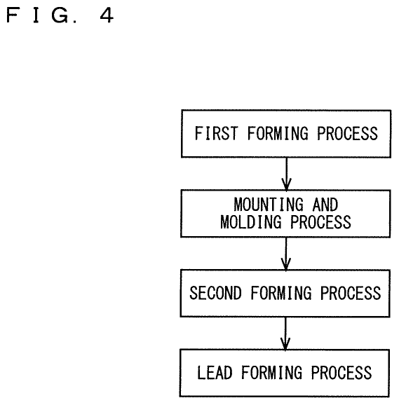

Next, the effect of the extension in the second direction of the terminals of the semiconductor device manufactured by using the lead frame 101 of the first embodiment will be described. In the description, at first, processes up to the formation of the semiconductor device by using the lead frame 101 is described. FIG. 4 is a flowchart showing part of processes of manufacturing the semiconductor device by using the lead frame 101, and the description follows the flowchart.

First, in the first forming process, the lead frame 101 having the die bond portion 1, the first terminal portion 3 composed of the first terminals 2A and 2B, the second terminal portion 5 composed of the second terminals 4, and the frame portion 6 is formed by applying press work to a flat plate of metal. This is what is shown in FIG. 1. In the first embodiment, the first recess portions 10 are formed in the frame portion 6 to sandwich the tip end portions of the first terminals 2A in this process.

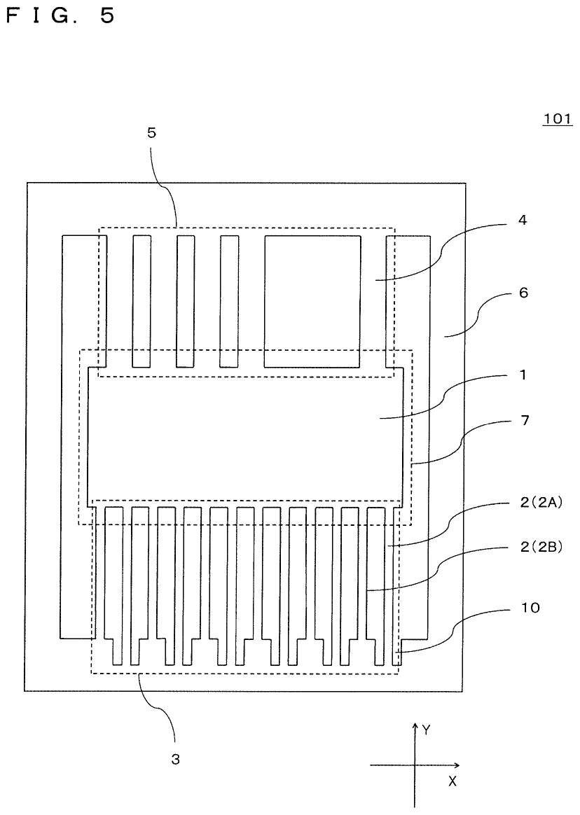

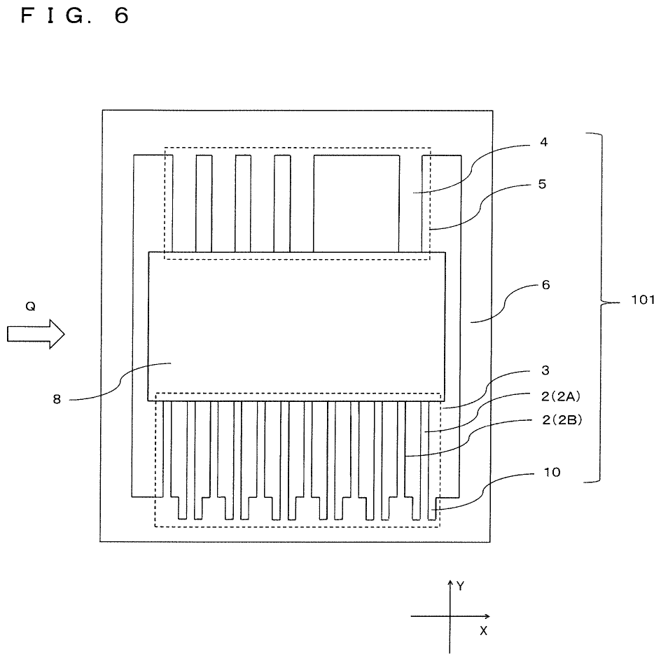

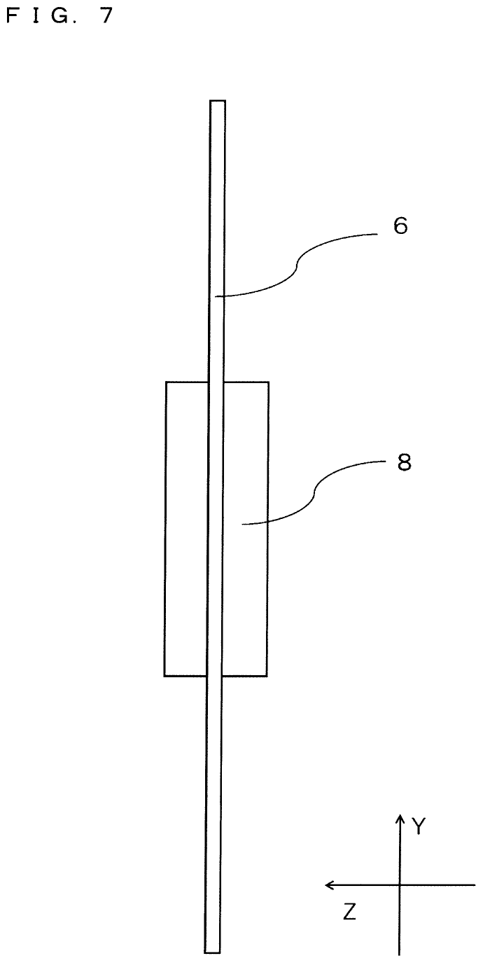

Next, the mounting and molding process is performed in which the semiconductor element is arranged on the lead frame 101 and sealed by the resin. FIG. 5 is a plan view showing the lead frame 101 before the mounting and molding process. In the mounting and molding process, the semiconductor element (not shown in the figures) are arranged on and electrically connected to the die bond portion 1 of the lead frame 101. After that, the semiconductor device is formed by sealing (molding) inside the sealing region 7 by the sealing resin being an insulating resin such that the sealing resin cover the semiconductor element. FIG. 6 is a plan view of the semiconductor device after the mounting and molding process, and FIG. 7 is a side view of the semiconductor device of FIG. 6 as seen from the Q direction. As shown in FIG. 6 and FIG. 7, in the semiconductor device after the mounting and molding process, the sealing region 7 is sealed by the sealing resin 8 from the front and back of the lead frame 101.

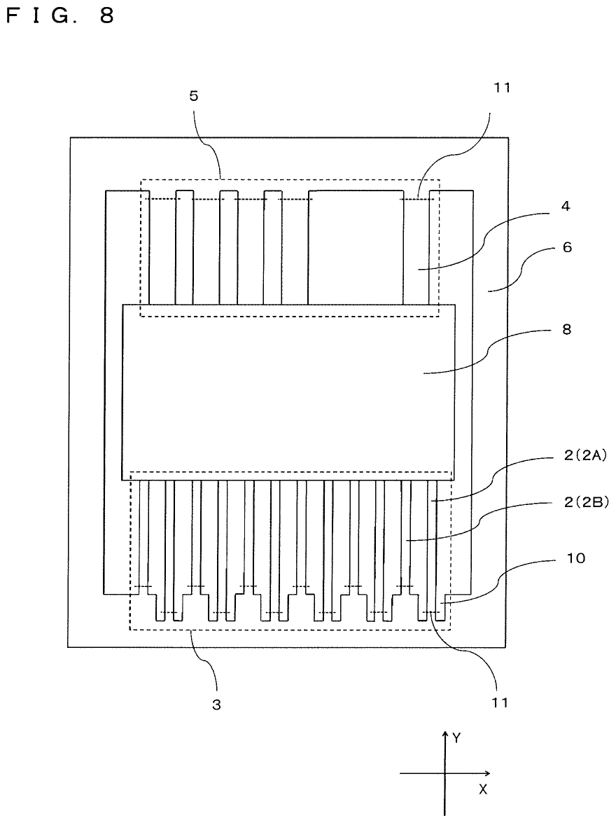

Next, in the second forming process, the frame portion 6 of the lead frame 101 is removed. FIG. 8 is a plan view of the semiconductor device before the second forming process. In the first embodiment, for each of the first terminals 2 and the second terminals 4, a cutting line 11 being a position for cutting is set near the frame portion 6. As for the first terminals 2A, the cutting lines are set in the portion which is sandwiched between the adjacent first recess portions 10. In the second forming process, the frame portion 6 is cut off by, for example, pushing the die of blanking press work against the cutting lines 11. Note that, in FIG. 8, although the cutting lines 11 are closer to the sealing resin 8 than the joint portions between the frame portion 6 and the first terminals 2 or the second terminals 4 are and parts of the tip end portions of the first terminals 2 and the second terminals 4 are left on the side of the frame portion 6, this is illustrated for clarity in explanation. To form the terminals as long as possible, the cutting lines are set as close to the frame portion 6 as possible after taking accuracy of positioning of the die or the like into consideration, and the terminals are cut such that the parts of the terminals left on the frame portion 6 is small.

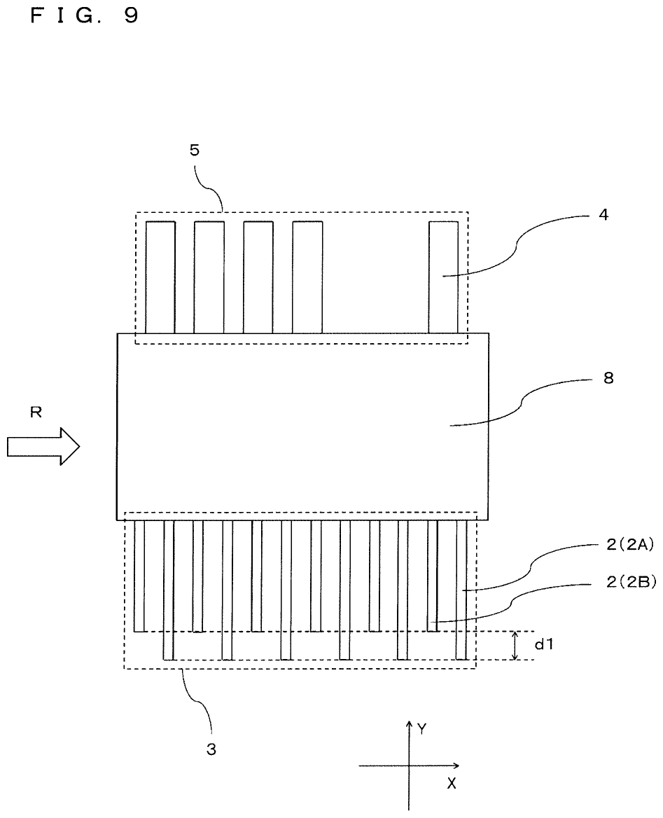

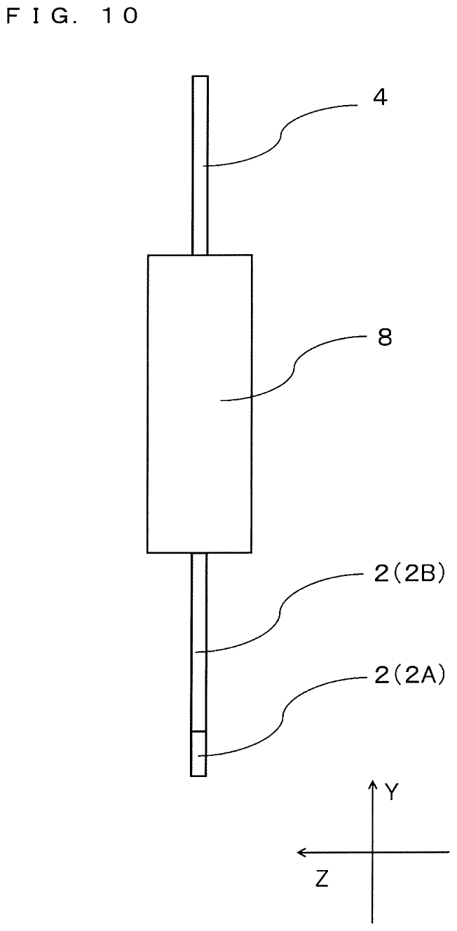

FIG. 9 is a plan view of the semiconductor device after the second forming process, and FIG. 10 is a side view of the semiconductor device of FIG. 9 as seen from the R direction. In the semiconductor device after the second forming process, as shown in FIG. 9 and FIG. 10, the frame portion 6 have been separated and removed, and the terminals are independent and disconnected with each other. In the first terminal portion 3 after the second forming process, the first terminals 2A, which are long terminals whose length from junction points with the sealing resin 8 to the tip end is longer, and the first terminals 2B, which are short terminals whose terminal length is shorter, are arranged alternately. The difference between the terminal length of the first terminals 2A and the terminal length of the first terminals 2B is equal to the recess amount in the second direction of the first recess portions, namely d1. Accordingly, the first terminals 2A being long terminals are longer than the first terminals 2B being short terminals preferably by 0.1 mm to 10 mm and more preferably by more than or equal to 0.2 mm and less than or equal to 5 mm.

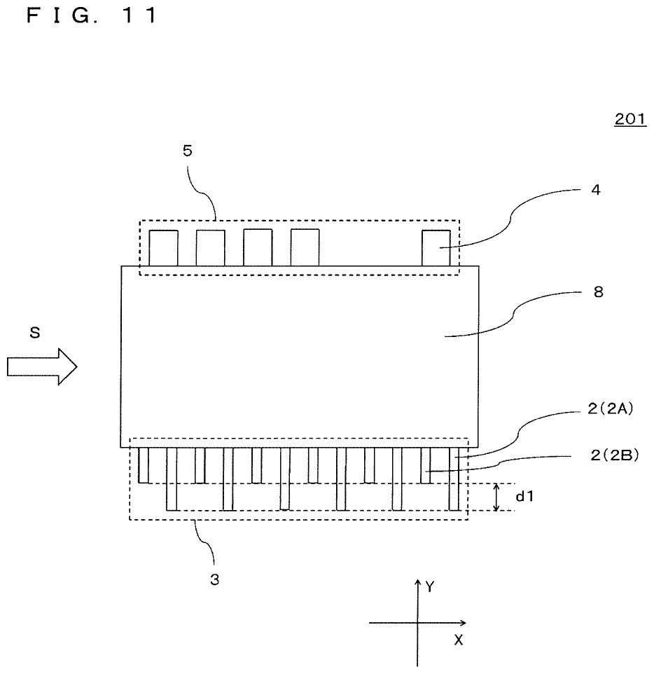

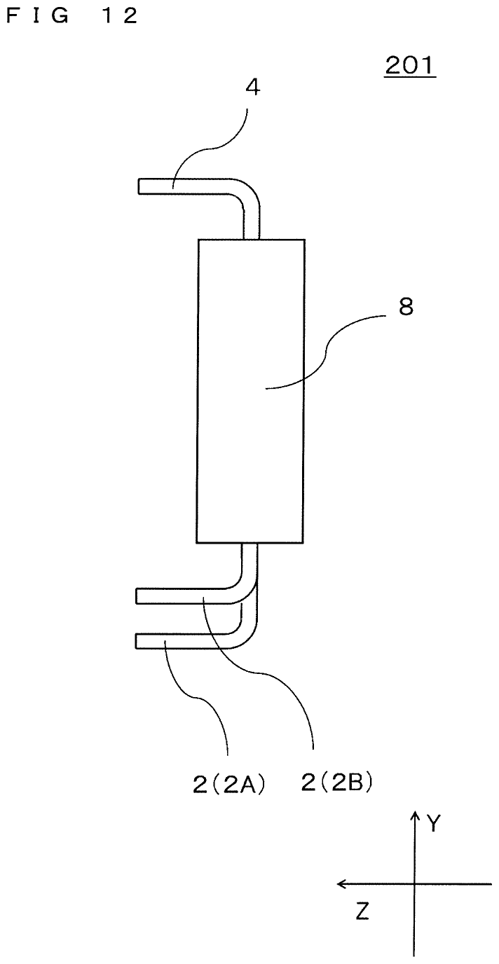

In the next lead forming process, the first terminals 2 and the second terminals 4 are bent to the third direction intersecting the first direction and the second direction. FIG. 11 is a plan view of the semiconductor device 201 after the lead forming process, and FIG. 12 is a side view of the semiconductor device 201 of FIG. 11 as seen from the S direction. The third direction (Z direction) is a direction facing an external board when the semiconductor device 201 is mounted on the board. In the first embodiment, as shown in FIG. 11, the positions where the first terminals 2A are bent and the positions where the first terminals 2B are bent are different in distance from the sealing resin 8 by d1, which is the recess amount of the first recess portions 10. As a result, the first terminals 2B being the short terminals become inner terminals which are bent near the sealing resin 8 and the first terminals 2A being the long terminals become outer terminals which are bent far from the sealing resin 8, to form the first terminal portion 3 having the region where the inner terminals and the outer terminals are arranged alternately. Such a configuration in which the inner terminals and the outer terminals are arranged alternately is referred to as staggered arrangement.

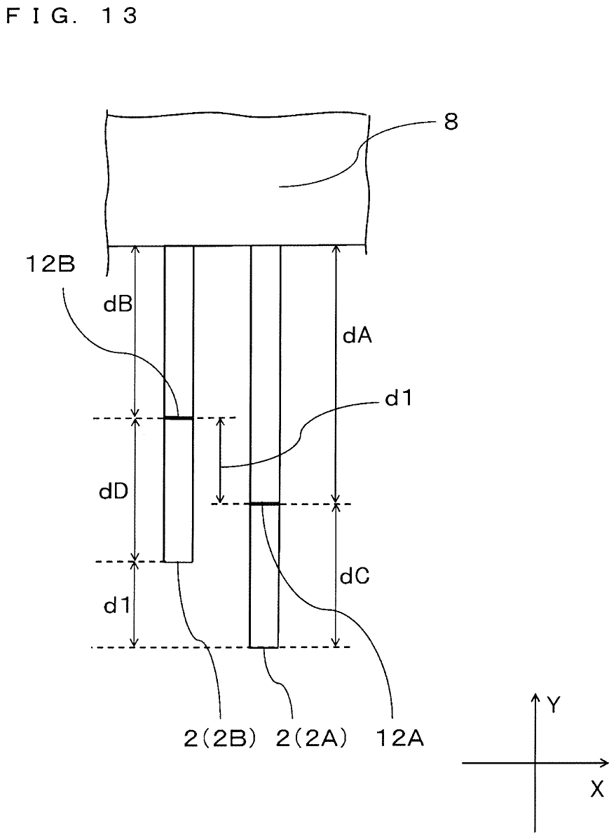

The positions at which the first terminals 2A and the first terminals 2B are bent in the lead forming process will be explained in more detail. FIG. 13 is an expanded plan view showing a part of the first terminal portion 3 of the semiconductor device 201 before the lead forming process. Positions where the first terminals 2A and the first terminals 2B are bent are indicated by the bending lines 12A and 12B respectively. As described above, before the lead forming process, regarding the lengths of the first terminals 2A being the long terminals and the first terminals 2B being the short terminals, the first terminals 2A are longer than the first terminals 2B by the recess amount d1 of the first recess portions 10. Here, in the first embodiment, the bending lines 12A and 12B are set such that the distance dA from the roots of the first terminals 2A, namely the junction points with the sealing resin 8, to the bending lines 12A is longer than the distance dB from the roots of the first terminals 2B, namely the junction points with the sealing resin 8, to the bending lines 12B by d1. In other words, the bending lines 12A and 12B are set such that dA−dB=d1 is satisfied. Accordingly, the distance dC from the tip ends of the first terminals 2A to the bending lines 12A and the distance dD from the tip ends of the first terminals 2B to the bending lines 12B is equal. The bending lines 12A and 12B are thus set, whereby the staggered arrangement in which the lengths of the first terminals 2A and the first terminals 2B from the junction points with the sealing resin 8 to the bending points through extension in the second direction differ by d1 is realized. Further, the lengths of the first terminals 2A and the first terminals 2B from the bending points to the tip ends are equal, as shown in FIG. 12.

Effects of the first embodiment will be described below. In describing the effects, the staggered arrangement of the lead terminals of the semiconductor device is described at first. The completed semiconductor device is used with each of the lead terminals connected to an external board such as a control board. At that time, bended tip end portion of each of the lead terminals is inserted to a conduction hole (through hole) provided in the control board and fixed by applying conductive material such as solder.

In a case where lead terminals of a semiconductor device are not arranged in a staggered way and the lead terminals of the same length in plan view are arranged, countermeasures such as reducing the diameter of the conduction holes provided in the control board are required to ensure insulation when distances between neighboring lead terminals are small. Nevertheless, reducing the diameter of the conduction holes leads to a problem that difficulty of manufacturing the control board increases. Also, processability deteriorates as high accuracy is required when the semiconductor device is mounted on the control board.

On the other hand, when the lead terminals are arranged in a staggered way, the conduction holes of the control board are also arranged in a staggered way, and distances between neighboring conduction holes can be large. As a result, difficulty of manufacturing the control board can be reduced and processability when the semiconductor device is mounted on the control board can be increased. For these reasons, staggered arrangement may be adopted especially when one wants to narrow the intervals between lead terminals.

In such a semiconductor device having lead terminals arranged in a staggered way, since the outer terminals are bent at positions farther from the sealing resin than positions where the inner terminals are bent, the outer terminals needs to be longer than the inner terminals before the bending. Nevertheless, if the entire lead frame is enlarged to lengthen the outer terminals, manufacturing processability of the lead frame or the semiconductor device using the lead frame deteriorates. Also, if the frame portion is narrowed, rigidity of the entire lead frame deteriorates. Further, if the length of the tip side of the bending points is short only in the outer terminals, there is a problem that it becomes difficult to join the semiconductor device to the control board.

The lead frame 101 of the first embodiment have the region in which the first terminals 2A, which are sandwiched between the first recess portions 10 adjacent in the first direction, and the first terminals 2B, which are not adjacent to and not sandwiched between the first recess portions 10, are arranged alternately. This allows that the first terminals 2A, which is to be the outer terminals, is cut from the frame portion 6 with the terminal length increased in the second direction by the amount of the first recess portions 10, and that the length of the outer terminals is increased without enlarging the lead frame 101. Also, by not providing the first recess portions 10 for the first terminals 2B, which is to be the inner terminals, deterioration of rigidity of the frame portion 6 can be suppressed.

Note that the first terminals 2A and the first terminals 2B are arranged, as shown in FIG. 11, in a staggered way in which the difference in length in plan view between the first terminals 2A and the first terminals 2B from the junction points with the sealing resin 8 to the bending points through extension in the second direction is d1, and d1 is preferably 0.1 mm to 10 mm. This is because it is desirable that d1 is 0.1 mm or more in order to obtain the effect by the staggered arrangement of suppressing deterioration of manufacturing processability of the lead frame or the semiconductor device using the lead frame, and if d1 is more than 10 mm the width of the frame portion 6 must be increased as described above and lead to deterioration of productivity.

Although in the first embodiment the first terminal portion 3 is composed of staggered arrangement in which the first terminals 2A, which are adjacent to and sandwiched between the first recesses 10, and the first terminals 2B, which are not adjacent to and not sandwiched between the first recess portions 10, are arranged alternately, not all terminals of the first terminal portion 3 need to be arranged alternately. It is sufficient to form first recess portions 10 in the frame portion 6 such that the tip end portions of the first terminals 2 which need to be longer are sandwiched between the first recess portions 10.

Although the bending lines 12A or 12B of the first terminals 2A or the first terminals 2B respectively are set such that lengths of the parts in the root side after the bending are different by the recess amount d1 of the first recess portions 10 as shown in FIG. 13 before the lead forming process, positions of the bending lines 12A or 12B are not limited thereto. In other words, bending positions may vary depending on, for example, the specification of the control board on which the semiconductor device 201 is mounted, and accordingly lengths of tip end side of bending positions may vary. It is only necessary that bending positions are set such that the first terminals 2A formed as the long terminals due to the first recess portions 10 become outer terminals and the first terminals 2B formed as the short terminal having shorter terminal length than that of the first terminals 2A become inner terminals.

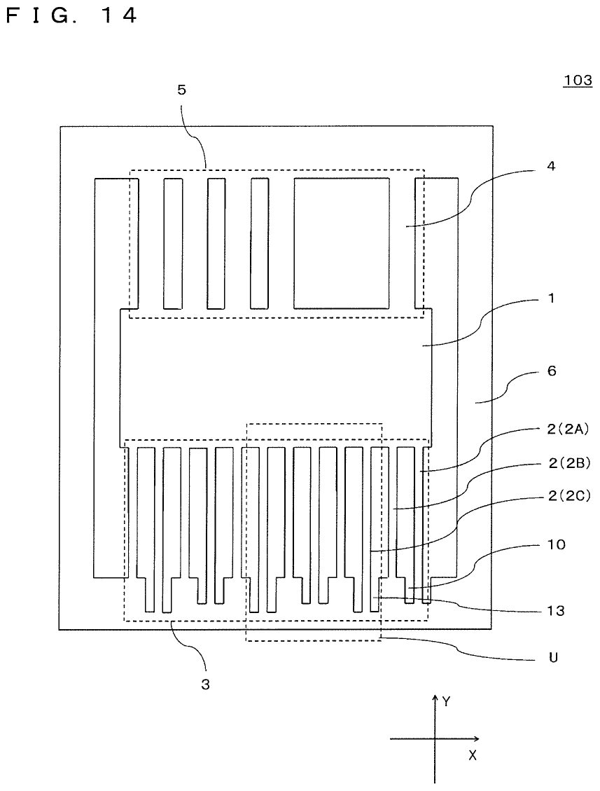

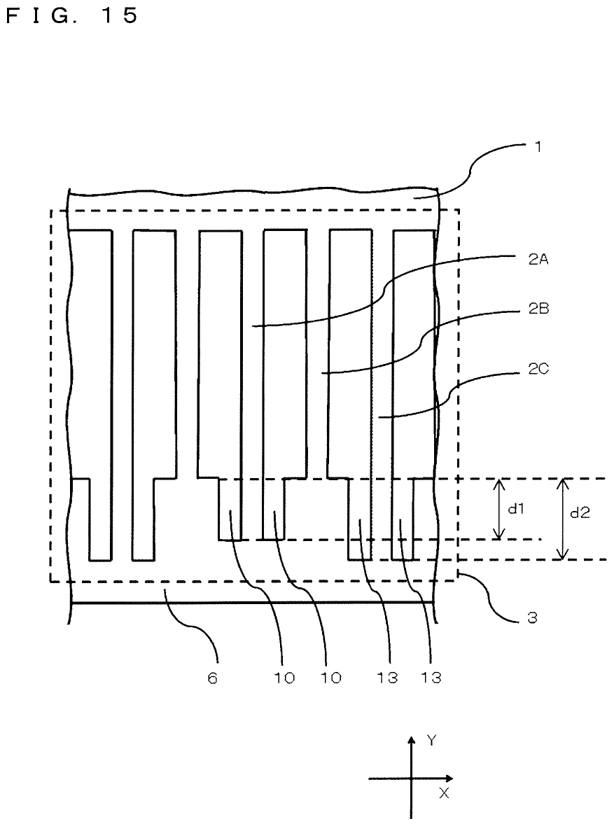

In the first embodiment, a configuration is described in which two types of terminals of different terminal lengths, the first terminals 2A and the first terminals 2B, are formed after the second forming process due to the provision of the first recess portions 10 in the first terminal portion 3. However, the configuration is not limited thereto, and more than two types of terminals of different terminal lengths may be formed. FIG. 14 is a plan view showing a lead frame 103 which is a modification example of the first embodiment. FIG. 15 is a plan view showing the part U of the lead frame 103 in FIG. 14 on an enlarged scale. As shown in FIG. 15, in the lead frame 103, in addition to the first recess portions 10 whose recess amount is d1, first recess portions 13 whose recess amount d2 is larger than d1 are provided to sandwich the tip end portions of the first terminals 2C. By using this configuration, after the frame portion 6 is removed in the second forming process, the first terminals 2A whose terminal length is longer than that of the first terminals 2B by d1 and the first terminals 2C whose terminal length is longer than that of the first terminals 2B by d2 can be formed, and totally three types of the first terminals 2 of different terminal lengths can be formed.

### Second Embodiment

In the first embodiment, the lead frame 101, in which the first terminals 2A and 2B are arranged alternately in the staggered way in the first terminal portion 3 and in which the first recess portions 10 sandwiching the tip end portions of the first terminals 2A are provided, are described. In the second embodiment, a lead frame 104 which further have the second recess portions 14 sandwiching the tip end portions of the second terminals 4 of the second terminal portion 5 arranged to face the first terminal portion 3 with interposition of the die bond portion 1. Since the second terminal portion 5 is the only difference from the first embodiment, only this difference will be described.

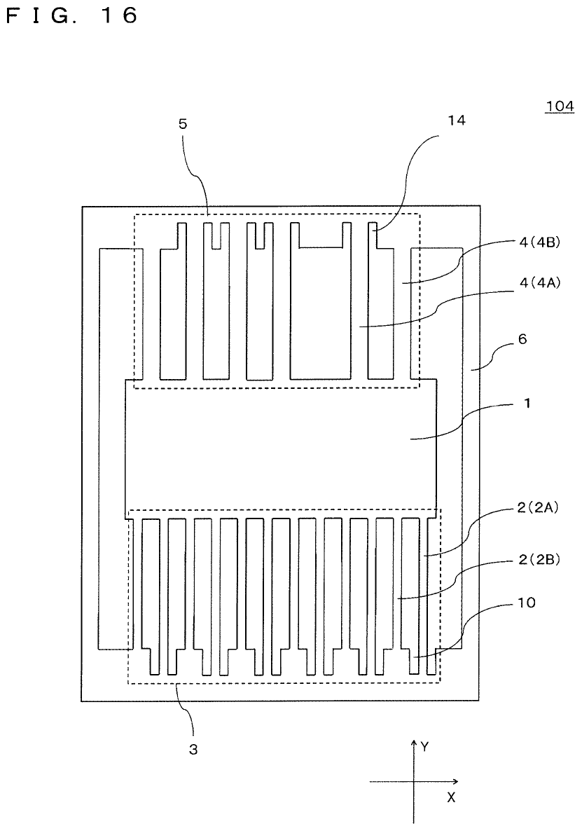

FIG. 16 is a plan view showing the lead frame 104 of the second embodiment. In the first terminal portion 3 of the lead frame 104, as described above, the first terminals 2A and 2B are alternately arranged in the first direction (X direction) and the first recess portions 10 sandwiching the tip end portions of the first terminals 2A are provided in the frame portion 6 as in the case of the first embodiment. In the second embodiment, a plurality of second recess portions 14 recessed along the second terminals 4 in the direction from the die bond portion 1 to the tip end portions of the second terminals 4 is further provided in the frame portion 6. The tip end portions of the second terminals 4A are sandwiched between the second recess portions 14 adjacent in the first direction, and the second recess portions 14 have a linear shape to form the shape of the second terminals 4A in the side of the tip end portions of the second terminals 4A. Also, the second recess portions 14 sandwiching the tip end portions of the second terminals 4B are not provided. The width in the first direction of the second recess portions 14 is preferably 0.5 mm to 3 mm as in the case of the first recess portions 10. Also, recess amount in the second direction of the second recess portions 14 is preferably 0.1 mm to 10 mm and more preferably in the range of more than or equal to 0.2 mm and less than or equal to 5 mm, as in the case of the first recess portions 10.

The second embodiment has an effect that the terminal length of the second terminals 4A is increased by providing the second recess portions 14 corresponding to the second terminals 4A. For example, in a case where there is a need to adjust positions of the tip end portions of the terminals by changing the terminal length due to a constraint of layout when the semiconductor device using the lead frame 104 is mounted on the control board, it is sufficient to provide the second recess portions 14 corresponding to only the second terminals 4 whose terminal length is to be increased. Further, by providing the second recess portions 14 corresponding to all of the second terminals 4, the width of the frame portion 6 in the region for joining can be narrowed while increasing the terminal length of the second terminals 4, and thus an effect that the size of the lead frame 104 is reduced is obtained.

### Third Embodiment

In the third embodiment, a lead frame 105 is described in which, to the configuration in which the first recess portions 10 and the second recess portions 14 are formed in the frame portion 6 as described in the first and second embodiment, holes for positioning in the manufacturing processes are further provided in regions where these recess portions are not provided.

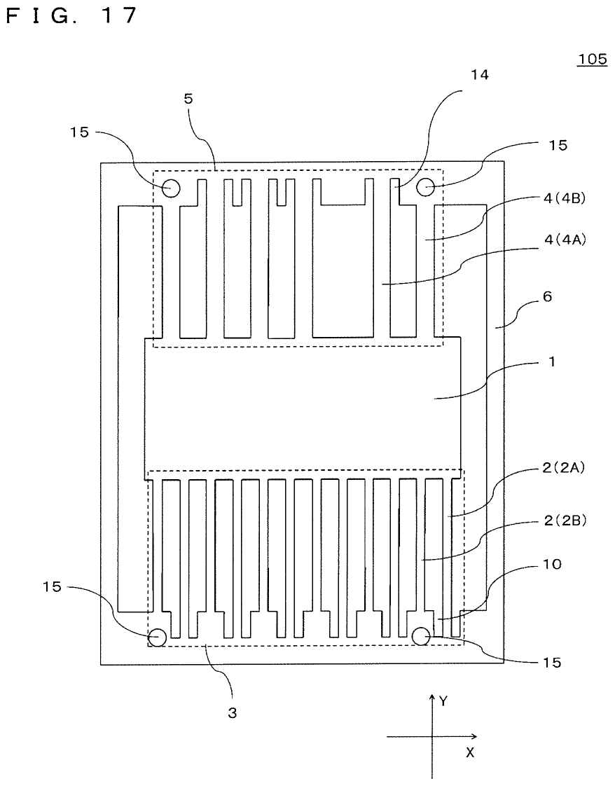

FIG. 17 is a plan view showing the lead frame 105 in the third embodiment. As in the case of the second embodiment, in the lead frame 105, the first terminals 2A and 2B are arranged alternately in a staggered way in the first direction (X direction) in the first terminal portion 3, and the first recess portions 10 sandwiching the tip end portions of the first terminals 2A and recessed along the first terminals 2A in the direction from the die bond portion 1 to the tip end portions of the first terminals 2A are provided in the frame portion 6. Also, the second terminals 4A and the second terminals 4B are arranged in the second terminal portion 5, and the second recess portions 14 sandwiching the tip end portions of the second terminals 4A and recessed along the second terminals 4A in the direction from the die bond portion 1 to the tip end portions of the second terminals 4A are provided in the frame portion 6. Further, in the third embodiment, positioning holes 15 being penetrating holes are provided in the frame portion 6 as shown in FIG. 17.

The positioning holes 15 are arranged in regions where the first recess portions 10 and the second recess portions 14 are not provided. Specifically, in FIG. 17, also in the region of the frame portion 6 in the lower side of the paper surface in which the first recess portions 10 are provided, the positioning holes 15 are arranged in positions overlapping, in the second direction, the tip end portions of the first terminals 2B for which the first recess portions 10 are not provided. Further, similarly, also in the region of the frame portion 6 in the upper side of the paper surface in which the second recess portions 14 are provided, the positioning holes 15 are arranged in positions overlapping, in the second direction, the tip end portions of the second terminals 4B for which the second recess portions 14 are not provides. Note that the positions of the positioning holes 15 are not limited thereto, and the positioning holes 15 may be arranged in any positions as long as the positioning holes 15 do not overlap the tip end portions of the first terminals 2A or the second terminals 4A, the first recess portions 10, or the second recess portions 14 in the second direction. The positioning holes 15 may be formed by blanking press work using a die similarly to each of the terminals in the first forming process, for example.

The positioning holes 15 are, for example, used for positioning in the mounting and molding process and the second forming process in which positions of the holes are read by a reading mechanism attached to a manufacturing device to recognize the position of the lead frame 105. In the third embodiment shown in FIG. 17, left and right side regions in the paper surface of the frame portion 6 are narrow, and the positioning holes 15 cannot be provided therein. Also, if the positioning holes 15 are arranged in the positions overlapping the tip end portions of the first terminals 2A or the second terminals 4A, the first recess portions 10, or the second recess portions 14 in the second direction, width of the frame portion 6 is locally narrowed, rigidity is decreased, and bending or deflection may occur. Therefore, by placing the positioning holes 15 to the positions not overlapping the tip end portions of the first terminals 2A or the second terminals 4A, the first recess portions 10, or the second recess portions 14 in the second direction, effect of suppressing the decrease in the rigidity of the frame portion 6 is obtained.

### Fourth Embodiment

In the first to third embodiment, the lead frames corresponding to the semiconductor devices having the lead terminals arranged in the staggered way are described. In the fourth embodiment, an integrated-type lead frame 106 of a semiconductor device in which a plurality of the lead frames shown in the first to third embodiments is arranged and integrated is described.

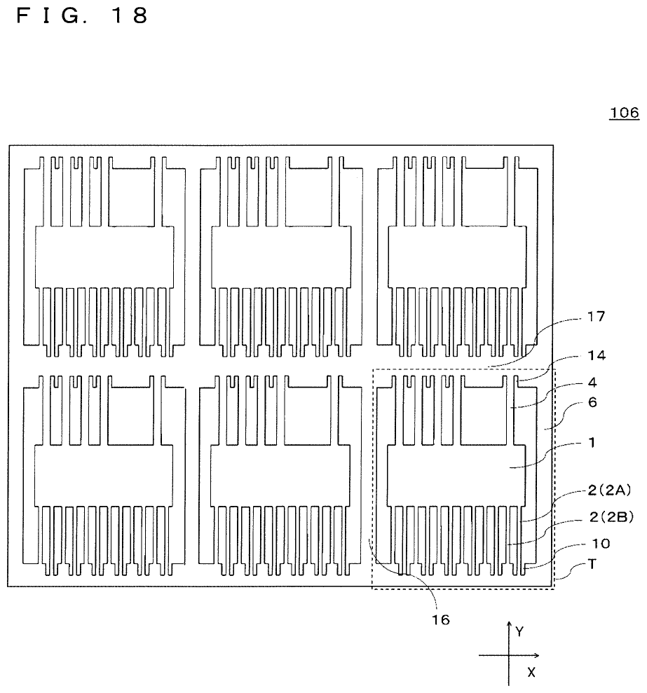

FIG. 18 is a plan view showing the integrated-type lead frame 106 of the semiconductor device in the fourth embodiment. As shown in FIG. 18, the lead frame 106 is a lead frame in which totally six lead frames (referred to as discrete lead frames) each having the first terminals 2, the second terminals 4, and the frame portion 6 and corresponding to one semiconductor device are arranged, three in the first direction (X direction) and two in the second direction (Y direction). In FIG. 18, the part T surrounded by the dashed lines corresponds to one discrete lead frame. The discrete lead frames are similar to the lead frames 101, 102, 103, 104, or 105 shown in the first to third embodiments. In the discrete lead frames shown in FIG. 18, for example, the first recess portions 10 and the second recess portions 14 are provided such that they sandwich the first terminals 2A and the second terminals 4 respectively. Note that although the lead frame 106, in which discrete lead frames for six semiconductor devices are arranged, is described in FIG. 18, the number of the discrete lead frames is not limited thereto as long as there are two or more discrete lead frames.

In the lead frame 106, the frame portions 6 of the discrete lead frames are shared by adjacent discrete lead frames and integrated. In particular, the regions of the frame portions 6 shared by adjacent discrete lead frames are referred to as middle portions. In other words, the lead frame 106 have middle portions 16 extending in the second direction between the discrete lead frames adjacent in the first direction and have a middle portion 17 extending in the first direction between the discrete lead frames adjacent in the second direction. The middle portion 17 is connected to any terminals of the first terminals 2 or the second terminals 4 on each side extending in the first direction of the middle portion 17. Arranging a plurality of lead frames in one lead frame 106 as described above enables to manufacture a plurality of semiconductor devices by using one lead frame 106 of semiconductor device and enables increase of manufacturing efficiency and reduction of usage of lead frame material. Also, in the semiconductor device formed by using the lead frame 106, in which the first recess portions 10 and the second recess portions 14 are provided in the frame portion 6 (the middle portion 17), width of the frame portion 6 can be narrowed, and more semiconductor devices can be manufactured from the same area of the lead frame while extending length of the terminals.

Note that although the configuration is described in which the lead frames having the first recess portions 10 and the second recess portions 14 are provided for the first terminals 2A and the second terminals 4 respectively in the fourth embodiment, the configuration is not limited thereto, and the lead frame 106 may be configured by arranging a plurality of lead frames having the first recess portions 10 only in the first terminal portion 3 as described in the first embodiment or a plurality of lead frames having the positioning holes 15 at parts of the frame portion 6 where the recess portions are not provided as described in the third embodiment.

Although some preferred embodiments of the present disclosure have been described, these preferred embodiments are presented as examples. Various omissions, replacements, and changes can be made without departing from the gist. In addition, each preferred embodiment can be combined. The scope of the present invention is shown not in the foregoing description but in the claims, and it is intended that all modifications that come within the meaning and range of equivalence to the claims are embraced here.

While the disclosure has been shown and described in detail, the foregoing description is in all aspects illustrative and not restrictive. It is therefore understood that numerous modifications and variations can be devised.

What is claimed is:

1. A lead frame of a semiconductor device comprising:
a first terminal portion in which a plurality of first terminals is arranged side by side in a first direction being a width direction of the first terminals;
a second terminal portion in which a plurality of second terminals wider in the first direction than the first terminals is arranged side by side in the first direction and which is arranged such that a die bond portion or a gap portion in which a semiconductor element is arranged is sandwiched between the first terminal portion and the second terminal portion; and
a frame portion to which a tip end portion of each of the first terminals and the second terminals being an end portion that is farther from the die bond portion or the gap portion is connected,
wherein first recess portions recessed along the first terminals in a direction from the die bond portion or the gap portion to the tip end portions are provided in the frame portion,
and wherein the first terminal portion comprises the first terminal the tip end portion of which is sandwiched between the first recess portions adjacent in the first direction and the first terminal the tip end portion of which is not sandwiched between the first recess portions adjacent in the first direction.

2. The lead frame of the semiconductor device according to claim 1, wherein
the first terminal portion comprises a region in which the first terminals the tip end portions of which are sandwiched between the first recess portions adjacent in the first direction and the first terminals the tip end portions of which are not sandwiched between the first recess portions adjacent in the first direction are alternately arranged.

3. The lead frame of the semiconductor device according to claim 1,
wherein a plurality of second recess portions recessed along the second terminals in a direction from the die bond portion or the gap portion to the tip end portions is provided in the frame portion,
and wherein the second terminal portion comprises the second terminal the tip end portion of which is sandwiched between the second recess portions adjacent in the first direction and the second terminal the tip end portion of which is not sandwiched between the second recess portions adjacent in the first direction.

4. The lead frame of the semiconductor device according to claim 1,
wherein second recess portions recessed along the second terminals in a direction from the die bond portion or the gap portion to the tip end portions are provided in the frame portion,
and wherein the tip end portions of all of the second terminals are sandwiched between the second recess portions adjacent in the first direction.

5. The lead frame of the semiconductor device according to claim 1,
wherein a positioning hole being a penetrating hole is arranged in the frame portion.

6. The lead frame of the semiconductor device according to claim 5,
wherein the positioning hole is provided in a position not overlapping, in a direction of the first terminals from the die bond portion or the gap portion to the tip end portions, the first recess portions or the first terminal the tip end portion of which is sandwiched between the first recess portions adjacent in the first direction.

7. The lead frame of the semiconductor device according to claim 6,
wherein the positioning hole is provided in a position overlapping, in a direction of the first terminals from the die bond portion or the gap portion to the tip end portions, the first terminal the tip end portion of which is not sandwiched between the first recess portions adjacent in the first direction.

8. The lead frame of the semiconductor device according to claim 3,
wherein a positioning hole being a penetrating hole is arranged in the frame portion, and
wherein the positioning hole is provided in a position not overlapping, in a direction of the first terminals from the die bond portion or the gap portion to the tip end portions, the first recess portions or the first terminal the tip end portion of which is sandwiched between the first recess portions adjacent in the first direction, or in a position not overlapping, in a direction of the second terminals from the die bond portion or the gap portion to the tip end portions, the second recess portions or the second terminal the tip end portion of which is sandwiched between the second recess portions adjacent in the first direction.

9. The lead frame of the semiconductor device according to claim 8,
wherein the positioning hole is provided in a position overlapping, in a direction of the first terminals from the die bond portion or the gap portion to the tip end portions, the first terminal the tip end portion of which is not sandwiched between the first recess portions adjacent in the first direction, or in a position overlapping, in a direction of the second terminals from the die bond portion or the gap portion to the tip end portions, the second terminal the tip end portion of which is not sandwiched between the second recess portions adjacent in the first direction.

10. The lead frame of the semiconductor device according to claim 4,
wherein a positioning hole being a penetrating hole is arranged in the frame portion, and
wherein the positioning hole is provided in a position not overlapping, in a direction of the first terminals from the die bond portion or the gap portion to the tip end portions, the first recess portions or the first terminal the tip end portion of which is sandwiched between the first recess portions adjacent in the first direction, or in a position not overlapping, in a direction of the second terminals from the die bond portion or the gap portion to the tip end portions, the second recess portions or the second terminal the tip end portion of which is sandwiched between the second recess portions adjacent in the first direction.

11. The lead frame of the semiconductor device according to claim 10,
wherein the positioning hole is provided in a position overlapping, in a direction of the first terminals from the die bond portion or the gap portion to the tip end portions, the first terminal the tip end portion of which is not sandwiched between the first recess portions adjacent in the first direction, or in a position overlapping, in a direction of the second terminals from the die bond portion or the gap portion to the tip end portions, the second terminal the tip end portion of which is not sandwiched between the second recess portions adjacent in the first direction.

12. The lead frame of the semiconductor device according to claim 1,
wherein the recess amount of the first recess portions along the first terminals in the direction from the die bond portion or the gap portion to the tip end portions is in a range of more than or equal to 0.1 mm and less than or equal to 10 mm.

13. An integrated-type lead frame of a semiconductor device in which a plurality of the lead frames according to claim 1 is arranged side by side at least in a second direction being an extending direction of the first terminals and the second terminals,
comprising a middle portion extending in the first direction of the lead frames between the lead frames adjacent in the second direction,
wherein the tip end portions of either of the first terminals and the second terminals are connected to each side of the frame portions extending in the first direction in the middle portion.

14. A semiconductor device comprising:
a lead frame having a plurality of first terminals arranged side by side in a first direction and a plurality of second terminals arranged side by side in the first direction;
a die bond portion or a gap portion arranged to be sandwiched between the first terminals and the second terminals in a second direction being an extending direction of the first terminals and the second terminals;
a semiconductor element arranged on the die bond portion or in the gap portion and electrically connected to the first terminals or the second terminals; and
an insulating sealing resin sealing the die bond portion or the gap portion and the semiconductor element,
wherein at least either of the plurality of first terminals and the plurality of second terminals has two or more different terminal lengths from junction points with the sealing resin to tip ends.

15. The semiconductor device according to claim 14,
wherein at least either of the plurality of first terminals or the plurality of second terminals includes a long terminal the terminal length of which is longer and a short terminal the terminal length of which is shorter, and
wherein in a plan view as seen from a third direction perpendicular to the first direction and the second direction, the long terminal is an outer terminal which is bent to the third direction in a farther position from the sealing resin than a position where the short terminal is bent, and the short terminal is an inner terminal which is bent to a direction same as the direction the outer terminal is bent to in a closer position to the sealing resin than the position where the long terminal is bent.

16. The semiconductor device according to claim 15, wherein
the terminal length of the long terminal is longer than that of the short terminal by more than or equal to 0.1 mm and less than or equal to 10 mm.
